(19) United States
(12) Patent Application Publication
(10) Pub. No.: US 2016/0170428 A1
(43) Pub. Date: Jun. 16, 2016

(54) DISPLAY DEVICE, POWER CONTROL SYSTEM, DISPLAY METHOD, POWER CONTROL METHOD, DISPLAY PROGRAM, AND POWER CONTROL PROGRAM

(71) Applicant: NEC CORPORATION, Tokyo (JP)

(72) Inventors: Masumi ICHIEN, Tokyo (JP); Yoshiaki SAKAE, Tokyo (JP); Norihisa IGA, Tokyo (JP); Masatsugu OGAWA, Tokyo (JP)

(73) Assignee: NEC CORPORATION, Tokyo (JP)

(21) Appl. No.: 14/908,880

(22) PCT Filed: Jun. 10, 2014
(86) PCT No.: PCT/JP2014/065824

§ 371 Date: Jan. 29, 2016

(30) Foreign Application Priority Data
Jul. 30, 2013 (JP) 2013-157662

(51) Int. Cl. G05F 1/66; G05B 15/02; G06T 11/20; G01R 21/133; G06F 3/0484

(52) U.S. Cl. CPC G05F 1/66; G01R 21/133; G06F 3/04847; G06T 11/206; G05B 15/02

(57) ABSTRACT

Comfortability can be visually displayed for a user in real time while power consumption is controlled. A display device communicates to/from a power control device for controlling power of a power consumption system including a plurality of apparatus. An input unit specifies a desired set value for each of the plurality of apparatus or a power consumption system including the plurality of apparatus. A display unit displays a display content corresponding to a degree of divergence in real time when an amount of upper limit power for the entire power consumption system including the plurality of apparatus is set, the degree of divergence being calculated based on a comparison between an actual set value for the plurality of apparatus having an amount of power being subjected to demand control based on an evaluation function set for the plurality of apparatus and the desired set value specified through the input unit.

### TECHNICAL FIELD

This invention relates to a display device, a power control system, a display method, a power control method, a display program, and a power control program to be used for a power consumption system including a plurality of apparatus.

### BACKGROUND ART

Various investigations are conducted for a system configured to control power. Examples of such a power control system include a home energy management system (HEMS) configured to control power for a household, a building energy management system (BEMS) configured to control power for a building, and a community/city energy management system (CEMS) configured to control power for a region of a self-governing community. An object of those power control systems is to establish a sustainable society by improving efficiency in using power or by positively using nature-derived energy (solar light, wind power, geothermal heat, or the like).

Hitherto, power control means power control conducted on a supply side such as a power plant. However, in recent years, with the rise of energy management systems, efforts to control power on a demand side are gathering momentum. This is called “demand side management”. The demand side management includes several kinds. For example, the demand side management includes a kind configured to control power demand with the aim of low a rate as possible so as to correspond to dynamic pricing for changing a power rate by hours and a kind configured to control the power demand in order to avoid a failure such as an outage by cutting a peak at a power demand peak. In a specific example of the latter, when the supply and demand of power become tight, a request for electricity saving is sent to the building. Each building is notified of power that the building is permitted to use as an upper limit (hereinafter referred to simply as “upper limit power”). Each building is recommended to suppress power consumption within the notified upper limit power.

It is expected that demands for controlling demand against the upper limit power may increase in the future. This is because both policies and public opinions are shifting from such a trend that power may be used as much as one wants to a tendency to use limited power in a good way. It is financially difficult to extend power stations in response to the demand, or it is said that the demand that may exceed a total power generation amount of the power stations is caused on approximately several days even in one year. It is reasonable to control the demand side than to increase power on the supply side under such a situation. Further, a simultaneous planned outage or the like does not need to be conducted as long as the demand can be controlled flexibly even when a disaster occurs, and hence demand control is meaningful in terms of crisis management.

Under such circumstances, researches are conducted on the demand control against the upper limit power. A method conducted for the current BEMS is a method of defining in advance a plan as to whether or not each apparatus (such as air conditioner, light fixture, or elevator) within the building is to be stopped when the request for electricity saving is received and, when the request for electricity saving is received, stopping the apparatus planned in advance based on the upper limit power. The demand control seems to be conducted easily with such a configuration, which is another story as to whether or not people within the building feel comfortable therewith.

Within the building, there is also an apparatus free from being subjected to the power control. For example, in a building that integrates commercial facilities, electricity is not wished to be saved for apparatus within the commercial facilities as much as possible. This is because such electricity saving as to cause the customers feel uncomfortable may cause defection of customers. In such a case, the apparatus within the commercial facilities are excluded from power control targets. In that case, the power being used by the commercial facilities constantly fluctuates, and to secure safety, such a demand control is conducted as to estimate a maximum amount of power to be used by the commercial facilities and to stop the apparatus in order. Even when the commercial facilities are not using the maximum amount of power, a floor having apparatus controlled falls into a situation in which excessive electricity saving is continued. In other words, while the request for electricity saving is satisfied, the electricity saving is conducted to an unnecessary degree, which forces people within the building to tolerate such electricity saving. In addition, there is a case where apparatus whose stopping is not planned are turned off, and hence the excessive electricity saving is conducted additionally for such apparatus.

In not only the above-mentioned example but also the current demand control, a prediction on the demand and supply is examined in advance along with plans as to when to, for example, use or stop apparatus under the prediction, to thereby conduct control in accordance with the plans. In a case of such control, the electricity saving provides an unnecessary margin in anticipation of a fact that a plan determined in advance may fail or existence of the apparatus whose power may not be controlled as in the above-mentioned example. In order to allow people living or working there to spend time with maximum comfort while satisfying the upper limit power, the plan determined in advance is required to be replaced with a method for comparing the upper limit power with total power being used currently and flexibly controlling the power of apparatus.

There are known various kinds of prior-art documents relating to this invention.

For example, in JP-B2-3351326 (Patent Document 1), there is disclosed a device configured to manage a total sum of power consumption of apparatus in an environment in which one or a plurality of apparatus that consume power exist. This device is capable of conducting optimum power consumption control by learning use statuses of the apparatus to sort the use statuses by steps and learning information on residents to convert the information into patterns. Further, the device disclosed in Patent Document 1 employs a configuration for simultaneously displaying merits and demerits expected to be provided to the residents by the power consumption control.

Further, in JP-A-2004-145396 (Patent Document 2), there is disclosed a “power transaction risk management method” involving deriving a stochastic process followed by a price when the demand exerts a geometric Brownian motion by using the Ito's lemma on the assumption that there is a fixed functional relation between power demand and power pricing, and deriving a differential equation that dominates the price of a derivative security written on such a stochastic process by using a no-arbitrage principle.

Further, in JP-A-2006-74952 (Patent Document 3), there is disclosed a “power peaking-off control system” configured to reduce a power peak by measuring an amount of power reduced after the control to compare the amount with the notified reduction amount of power, and conduct determination so as to achieve the reduction amount of power based on the comparison.

In addition, in JP-A-2010-124605 (Patent Document 4), there is disclosed a “power consumption prediction device” configured to compare power consumption amount data pieces with each other, apply an evaluation function thereto, and extract power consumption data exhibiting a high correlation value from track record data.

In JP-A-2010-146387 (Patent Document 5), there is disclosed an “energy saving behavior evaluation device” configured such that an energy saving behavior evaluation unit acquires data for yesterday or last week from an apparatus information database, conducts an evaluation by using an evaluation function, and records a value obtained by this evaluation in an evaluation result database.

### PRIOR ART DOCUMENTS

### Patent Document

### Patent Document 1: JP-B2-3351326

### Patent Document 2: JP-A-2004-145396 ([0091])

### Patent Document 3: JP-A-2006-74952 ([0022], [0023])

### Patent Document 4: JP-A-2010-124605 ([0079])

### Patent Document 5: JP-A-2010-146387 ([0024])

### SUMMARY OF THE INVENTION

### Problem to be Solved by the Invention

As described above, demand control for flexibly controlling power of apparatus is desired. However, it is difficult to realize the demand control in actuality, and no method effective therefor has been proposed. Main reasons that make it difficult to realize the demand control are as follows. The first reason is that there are a large number of apparatus to be controlled (controllable apparatus). The second reason is that tracking of real-time fluctuations in the power of an apparatus that is not a control target (uncontrollable apparatus) is not allowed. A large building includes as many as 1,000 air conditioners, light fixtures, and the like to be controlled, and further increasing control targets are required to meet a request for electricity saving in cooperation between buildings. In the future, at a GEMS level, on the order of 10 times as many apparatus as in BEMS are to be controlled. It is extremely difficult to control those apparatus in real time so as to satisfy upper limit power in consideration of power fluctuations of the apparatus that is not a control target (uncontrollable apparatus). An infinite number of situations and combinatorial problems of apparatus control need to be solved.

Further, under the demand control, a desired set value specified by a user and an actual set value realized by the demand control in actuality sometimes differ from each other depending on a constraint of the power consumption. In particular, the power consumption of the apparatus becomes relatively large in summer or in daytime, which tends to raise a degree to which the desired set value and the actual set value diverge from each other.

In that case, when any information is not presented to the user, the user is trifled with various kinds of information based on unfounded speculations that a failure or a malfunction has occurred in the apparatus, with the result that a tangle of information and perplexity may be caused, which is undesirable.

In general, when pieces of information on comfortableness, convenience, and the like based on influence of the demand control of the apparatus are provided one by one, the user is allowed to grasp to which extent the user is to tolerate the situation, and is therefore allowed to settle for the apparatus subjected to the demand control so as to realize maximum comfortableness under the constraint of the maximum power consumption.

In Patent Document 1, use statuses of the apparatus and information on residents are learned to conduct optimum power consumption control, and degradation from the current convenience or comfortability, which is expected when optimum saving means is selected, is displayed. However, the control method disclosed in Reference Document 1 is not the demand control, and hence expected future degradation information can be displayed for the user, but there is a problem that the current degree of divergence is inhibited from being displayed in real time to be known to the user.

It is desired to visually display the convenience or the degree of comfortableness (hereinafter referred to as “comfortability”) for the user in real time while controlling the power consumption in the above-mentioned manner.

It is an object of this invention to provide a display device, a power control system, a display method, a power control method, a display program, and a power control program that solve the above-mentioned problems.

### Means to Solve the Problem

According to one aspect of the present invention, there is provided a display device, including: a storage unit configured to store display information corresponding to a degree of divergence between a user's desired value and a set value; and a display unit including a display configured to display the display information corresponding to the degree of divergence.

Further, according to another aspect of the present invention, there is provided a display device configured to communicate to/from a power control device that is configured to control power of a power consumption system including a plurality of apparatus, the display device including: an input unit configured to specify a desired set value for each of the plurality of apparatus or a power consumption system including the plurality of apparatus; and a display unit configured to display a display content corresponding to a degree of divergence in real time when an amount of upper limit power for the entire power consumption system including the plurality of apparatus is set, the degree of divergence being calculated based on a comparison between an actual set value for the plurality of apparatus having an amount of power being subjected to demand control based on an evaluation function set for the plurality of apparatus and the desired set value specified through the input unit.

### Effect of the Invention

According to the aspects of the present invention, the comfortability may be visually displayed for a user in real time while power consumption is controlled.

Further advantages and an embodiment of this invention are described below in detail with reference to descriptions and the accompanying drawings.

### BRIEF DESCRIPTION OF THE DRAWING

FIG. 1 is a schematic configuration diagram for illustrating an entirety of a power control system according to one embodiment of this invention.

FIG. 2 is a block diagram for illustrating a configuration of a display device according to the one embodiment of this invention.

FIG. 3 is a block diagram for illustrating a configuration of a power control device according to the one embodiment of this invention.

FIG. 4 is a table for showing an example of a display content indicated in a display unit of the display device illustrated in FIG. 2.

FIG. 5 is a graph for showing a control result obtained by using the power control device described in the one embodiment of this invention.

### MODE FOR EMBODYING THE INVENTION

Previously in the specification of Japanese Patent Application No. 2013-131342, the present applicant has proposed the invention for maintaining a comfortability while usable power is being sufficiently used in a state in which an electricity saving state is maintained by power consumption control. A power control device therefor is configured to conduct such control that, when an amount of upper limit power for an entire power consumption system is specified, an evaluation function is set for each of controllable apparatus, and derivative values of the evaluation function for the respective controllable apparatus are equalized. This power control device allows the control to be conducted so as to eliminate a difference between the amount of the upper limit power and an amount of current power of the entire power consumption system.

However, when the power control device is used in the above-mentioned state in which the amount of the upper limit power is specified, an individual apparatus included in the power consumption system does not always conduct an operation desired by a user. For example, when the controllable apparatus is an air conditioner, the air conditioner does not always operate toward a set temperature desired by the user. Further, when the controllable apparatus is a lighting apparatus, the lighting apparatus does not always operate so as to achieve an illuminance desired by the user.

In general, electric apparatus such as an air conditioner and a lighting apparatus are often controlled through a remote controller (hereinafter referred to as “remote control”). The remote controls used for a normal air conditioner, a normal lighting apparatus, and the like are configured to control the air conditioner and the lighting apparatus so that temperature and luminance match with a set temperature, a set illuminance, and the like desired by the user.

Therefore, also when the normal remote control is applied to an apparatus controlled by the power control device described in Japanese Patent Application No. 2013-131342, there is a fear that the user may feel uncomfortable by failing to obtain a desired environment, or that the user may become suspicious about the apparatus to be used.

In the power consumption system using the above-mentioned power control device, this invention allows the user's discomfort or suspicion about the apparatus to be alleviated by visually displaying the comfortability, which corresponds to a degree of divergence between an actual set value subjected to actual control and a desired set value specified by the user, for the user in real time.

An embodiment of this invention is described below in detail with reference to the accompanying drawings.

First, a power control system 1 according to the embodiment of this invention is described in detail with reference to the accompanying drawings. To facilitate an understanding of this invention, the following description is directed to a case where this invention is applied to the power control device described in Japanese Patent Application No. 2013-131342, but this invention is not limited thereto in any way.

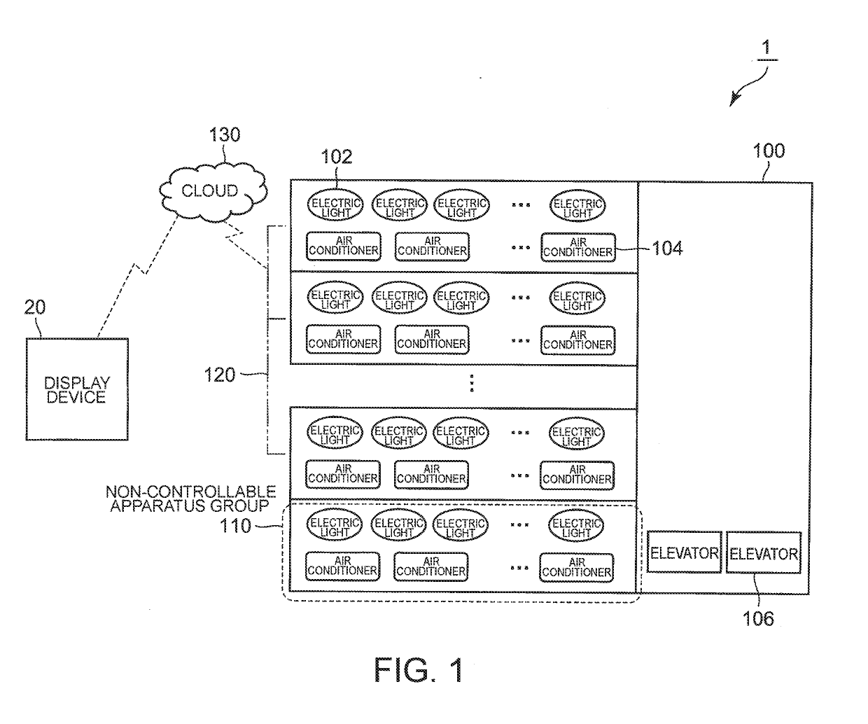

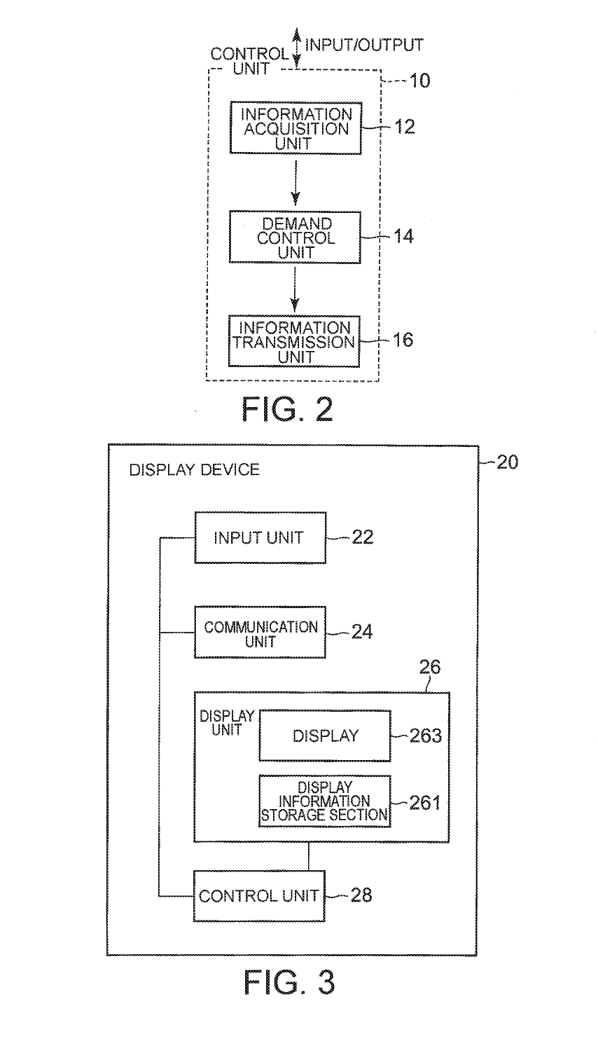

FIG. 1 is a diagram for illustrating a schematic configuration of the power control system 1 to which a power control device according to this embodiment may be applied. The power control system 1 illustrated in FIG. 1 includes a power consumption system 100 including a plurality of apparatus arranged in a building, a cloud 130 (including a power control device 10 illustrated in FIG. 2 formed on a cloud), and a display device 20 according to this invention configured to communicate to/from the plurality of apparatus and the power control device 10 formed on the cloud through a communications network.

The power consumption system 100 includes, as the apparatus, a large number of electric lights 102, a large number of air conditioners 104, and a plurality of elevators 106. In FIG. 1, a “non-controllable apparatus group” surrounded by the dotted line represents apparatus excluded from control targets (apparatus that are not control targets) 110. The other apparatus are control targets 120. In this case, the apparatus excluded from the control targets (apparatus that are not the control targets) 110 are referred to also as “uncontrollable apparatus”, and the control targets 120 are referred to also as “controllable apparatus”. In other words, a large number of apparatus are classified into the controllable apparatus 120 and the uncontrollable apparatus 110.

To give a brief description, this invention relates to a method of controlling the control targets 120 in real time so as to satisfy the upper limit power in consideration of the power fluctuations of the apparatus that are not the control targets 110 when the power consumption system 100 thus includes the large number of apparatus 102, 104, and 106.

First, priorities are required to be assigned to the apparatus. The priorities are assigned so that a higher priority is assigned to an apparatus that is more important to objects and persons that are active in the building. In other words, this allows creation of a situation that hardly causes the apparatus having a higher priority to be stopped even when the apparatus are stopped under a request for electricity saving, which allows control to be conducted so as not to inhibit activities of the objects and the persons at the maximum.

The priority as to whether or not to stop the apparatus under power restrictions differs depending on characteristics of a floor even among the same apparatus. For example, in a server room, the priority of the air conditioner 104 is high, but the priority of the electric light 102 is low. On the other hand, the priority of the electric light 102 on an office floor is higher than the priority of the electric light 102 in the server room. To take more detailed control into consideration, it is conceivable to, for example, increase the priority of the air conditioners 104 on a floor having a large number of persons, and to decrease the priority of the air conditioners 104 on a floor having a small number of persons. In this manner, the priorities of the apparatus within the building are diverse.

A method conceived of most easily among the method of controlling apparatus by assigning priorities thereto is a method of arranging the apparatus by assigning a position in a priority order to every apparatus. This method may be allowed when the number of apparatus is limited or when the priorities are clear. However, in actuality, there are many cases where the number of apparatus is enormous and a large number of apparatus have the priorities in the same level. In addition, in the case of the building or other such case, the priorities of the apparatus may often change due to a change in layout.

In view of such circumstances, the method of arranging the apparatus by assigning the position in the priority order to every apparatus is not realistic. Therefore, while the priorities are assigned to the apparatus, it is preferred that a priority be set independently for each apparatus. The situation in which the priority is set independently may in turn allow a situation in which priorities in the same level are assigned to different apparatus.

When the priorities are set to the apparatus independently in this manner, the setting of the priorities is simple and easy to be associated with comfortableness for the actual activities of the people, but the control becomes complicated. When there exist different apparatus having the same priority, it is not easy to determine how much power is to be allocated to which. In addition, it is less easy to satisfy the upper limit power in consideration of the power fluctuations of the apparatus that are not the control targets 110.

In order to realize such difficult real-time control, the “autonomous and distributed load balancing method” that has been filed by the present applicant is applied to this invention. The present applicant has filed the invention relating to a method of controlling a plurality of elements in an autonomous and distributed manner and carrying out load balancing for overall optimization. In this case, the element may be any element such as a server or a generator, and in this invention, the apparatus whose power control is to be conducted corresponds to the element. Further, in the method for autonomous and distributed load balancing, an evaluation function suitable for performance of an element is first set for each of the elements.

Details including an outline of the evaluation function, setting of the evaluation function, and the autonomous and distributed load balancing method using the evaluation function are described in Japanese Patent Application No. 2013-131342 as a related application, and hence only a schematic description thereof is provided herein.

A problem for causing elements whose evaluation function is a convex function to cooperate with one another for overall optimization (state in which a total sum of the values of the evaluation function for the respective elements becomes maximum) is known as a convex programming problem. Further, the convex programming problem may be optimized under a situation in which the derivative values of the evaluation function in operation levels of the respective elements are equal to one another. Through use of this fact, the following differential equation is used as described in Japanese Patent Application No. 2013-131342.

$$\frac{d {λ}_{i}}{d t} = {K}_{1} \frac{Dem - {P}_{t}}{Dem} + {K}_{2} ( \frac{d {f}_{l}}{d {λ}_{i}} - \frac{d {f}_{k}}{d {λ}_{k}} )$$

In the equation, Pₜ represents an amount of power usage of the entire building. In a case other than the control of the building, Pₜ represents an amount of power usage (amount of current power) of the entire power consumption system 100 to be set as a target. Pₜ includes all the amounts of power used by the controllable apparatus 120 and the uncontrollable apparatus 110. The amount of the upper limit power is set as Dem. In the case of this example, λᵢ represents power of a controllable apparatus i, fᵢ represents an evaluation function set for the controllable apparatus i, λₖ represents power of an adjacent controllable apparatus k, fₖ represents an evaluation function set for the adjacent controllable apparatus k, and K₁ and K₂ represent gains of power changes.

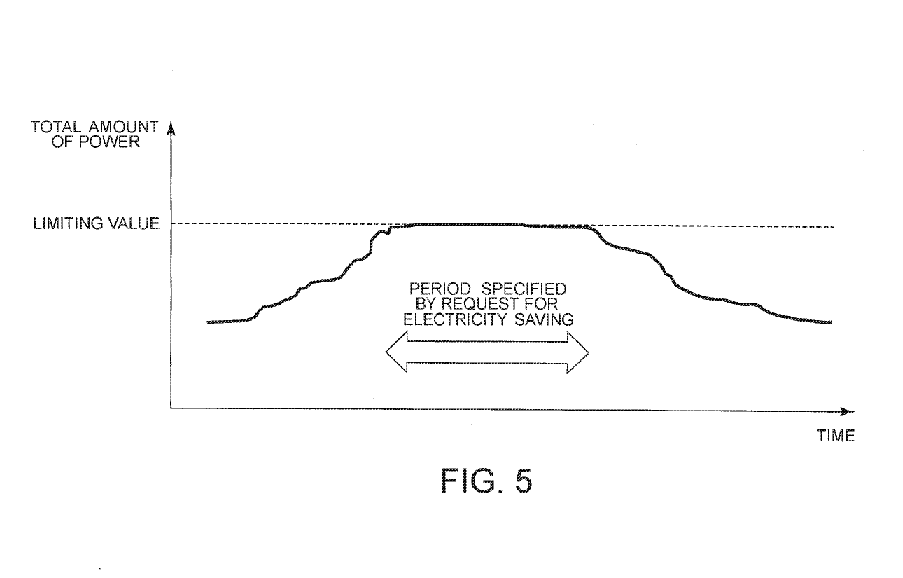

A control result shown in FIG. 5 is obtained through use of the power control device described in Japanese Patent Application No. 2013-131342. As shown in FIG. 5, when the amount of power usage approaches the amount of power specified by the request for electricity saving, the apparatus are stopped based on the priorities, to thereby allow the amount of power of the entire building to be controlled to the amount of power that meets the request for electricity saving.

In FIG. 2, a configuration of the power control device 10 according to this embodiment and processing thereof are illustrated. The control unit (power control device) 10 formed on the cloud 130 includes an information acquisition unit 12, a demand control unit 14, and an information transmission unit 16.

The information acquisition unit 12 acquires the power of the controllable apparatus 120 within the building and the current power of the entire building, and passes the acquired power to the demand control unit 14. The demand control unit 14 is capable of executing Math. 1, and calculates control values (temperature and apparatus count) to be set for the respective controllable apparatus 120 at the next time based on Math. 1. The demand control unit 14 approximates those values to actually controllable values, and outputs the values to the information transmission unit 16. The information transmission unit 16 transmits the received control values, which are to be set for the respective controllable apparatus 120 at the next time, to the respective controllable apparatus 120. After that, the above-mentioned processing is repeated. The demand control unit 14 assumes that the respective apparatus are virtually connected to one another through a network, and determines apparatus adjacent thereto in view of the network.

In FIG. 3, a schematic configuration of the display device 20 according to this embodiment is illustrated. The display device 20 is, for example, a remote control or a smartphone, and is a device capable of communicating to/from another apparatus (in this case, power control device 10 illustrated in FIG. 2). The display device 20 illustrated in FIG. 3 includes an input unit 22, a communication unit 24, and a display unit 26.

The input unit 22 includes a button or a touch panel that allows the user (subject person) to specify his/her desired set value for a plurality of apparatus. When the desired set value is input through the input unit 22, the communication unit 24 transmits the specified desired set value to the power control device 10. With this operation, setting information on the evaluation function having a peak value correlated with the specified desired set value is set for each of the plurality of apparatus or the power consumption system 100 including the plurality of apparatus.

Further, the communication unit 24 includes a transceiver configured to transmit and receive an infrared ray or a radio signal, and receives display information corresponding to the degree of divergence between the actual set value for each apparatus controlled under the demand control conducted by the power control device 10 and the desired set value specified by the user, to display the display information on the display unit 26 formed of liquid crystal, organic EL, or the like. In addition, the display device 20 illustrated in FIG. 3 includes a control unit 28 configured to control the input unit 22, the communication unit 24, and the display unit 26. The control unit 28 includes a storage unit configured to store a program and a CPU, and the CPU controls the input unit 22, the communication unit 24, and the display unit 26 in accordance with the program stored in the storage device.

Specifically, when the user's desired value is input through the input unit 22 and when the actual set value is received from the power control device 10 through the communication unit 24, the control unit 28 calculates the degree of divergence between the desired value and the actual set value. The degree of divergence calculated by the control unit 28 is supplied to the display unit 26. The display unit 26 includes a display information storage section 261, and the display information storage section 261 displays the display information corresponding to the degree of divergence on a display 263. The display information corresponding to the degree of divergence displayed on the display 263 indicates, for example, the comfortability.

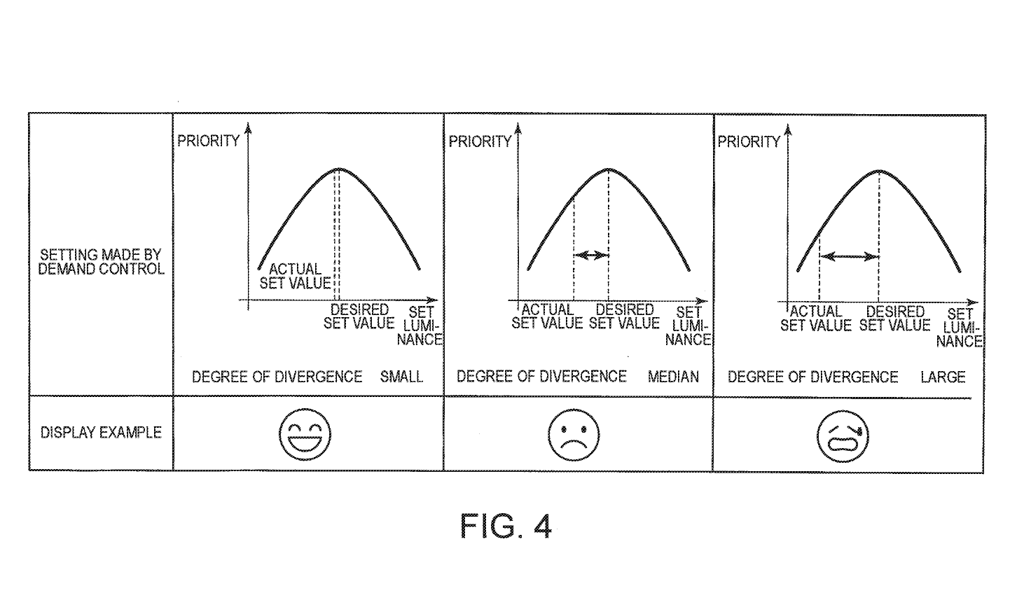

For example, a display content such as an emoticon or a character shown in FIG. 4 is displayed on the display unit 26 to notify the person living or working there of real-time information on the apparatus under the demand control. Further, the display unit 26 is also capable of displaying a ratio of power and a change in control for each of the plurality of apparatus.

FIG. 4 is a table for showing a relationship between a setting made by the demand control under the environment in which the upper limit power is set and a display example of the display unit 26 of the display device 20.

As shown in FIG. 4, when a difference between the desired set value specified by the user and the actual set value for the plurality of apparatus having the amount of power being subjected to the demand control based on the evaluation function set for the plurality of apparatus is small, that is, when the degree of divergence is small, for example, a smiley emoticon is displayed on the display unit 26. When the difference between the desired set value specified by the user and the actual set value for the plurality of apparatus having the amount of power being subjected to the demand control based on the evaluation function set or the plurality of apparatus is median, that is, when the degree of divergence is approximately median, an ordinary emoticon is displayed on the display unit 26. Further, when the difference between the desired set value specified by the user and the actual set value for the plurality of apparatus having the amount of power being subjected to the demand control based on the evaluation function set for the plurality of apparatus is large, that is, when the degree of divergence is large, a sweating emoticon is displayed on the display unit 26. By viewing the display content displayed on the display unit 26, the user is allowed to visually identify the degree of tolerance forced under the situation in which the apparatus are being subjected to the demand control.

In FIG. 4, an example of visually displaying the emoticon on the display 263 is shown, but this invention is not limited to the emoticon, and the display may be conducted by using symbols or characters.

In this manner, in the display device 20 and the power control system 1 according to this embodiment, when the amount of the upper limit power for the entire power consumption system is set, the plurality of apparatus are subjected to the demand control based on the evaluation function, and the current convenience and comfortableness are displayed for the user based on the degree of divergence. Further, the power of a large-scale power consumption system is allowed to be controlled in real time so as to satisfy the upper limit power in consideration of the power fluctuations of the apparatus that are not the control targets. The use of this method allows effective use of the power up to the upper limit power and maximization of the comfortableness for the person living or working there.

The embodiment is described with reference to FIG. 1 by taking the case where transmission and reception are conducted between the power control device 10 provided within the cloud and the display device 20. However, this invention is not limited thereto. For example, when the power control devices are provided so as to correspond to the air conditioners 104 or the plurality of electric lights 102 illustrated in FIG. 1, this invention may be similarly applied to a case where those power control devices and the display device 20 communicate to/from each other.

Note that, the power control method to be carried out in the power control device can be stored as a program that is executable by a computer on a recording medium such as a magnetic disk such as a floppy (trademark) disk or a hard disk, an optical disc such as a CD-ROM or a DVD, a magneto-optic disk (MO), or a semiconductor memory, and can be distributed. Further, the control unit 28 of the display device 20 may include a program for displaying the display information corresponding to the degree of divergence, and this program may be stored in a recording medium or the like, or may be downloaded through the Internet.

Moreover, as long as the recording medium can store a program, and can be read by a computer, a storage form may be any form.

Moreover, an operating system, middleware such as database management software, and network software, or the like operating on a computer may carry out a part of the respective pieces of the processing based on instructions of a program installed from the recording medium on the computer.

Further, the recording medium is not limited to a medium independent of the computer, and includes a recording medium for storing or temporarily storing a downloaded program transmitted via a LAN, the Internet, or the like.

Moreover, the number of the recording media is not limited to one. Such a case that the processing in the above-mentioned embodiment is carried out from a plurality of media is included in the recording medium according to this invention, and a medium configuration may be any configuration.

The computer carries out the respective processing based on programs stored in a recording medium, and may include any configuration such as an apparatus constructed by a personal computer, a system in which a plurality of apparatus are connected via a network, or the like.

Moreover, the computer is not limited to a personal computer, includes an arithmetic processing apparatus included in an information processing apparatus, and is an apparatus or device capable of using a program to realize the functions of this invention.

This invention has been described above with reference to the embodiment, but this invention is not limited to the above-mentioned embodiment. The configurations and the details of this invention may be subjected to various changes that may be understood by a person skilled in the art within the scope of this invention.

In the above-mentioned embodiment, an example of a HEMS corresponding to the power control of the building is described, but it should be understood that the same control is also applicable to other kinds of energy management conducted by a HEMS, a CEMS, or the like.

In the first embodiment, the control is conducted by uploading data onto a server in the cloud, but this invention is not limited to the cloud, and the same control may be conducted by installing the server within a building or a household.

This application claims priority from Japanese Patent Application No. 2013-157662, filed on Jul. 30, 2013, the entire disclosure of which is incorporated herein by reference.

### REFERENCE SIGNS LIST

1 power control system
10 control unit (power control device)
12 information acquisition unit
14 demand control unit
16 information transmission unit
20 display device
22 input unit
24 communication unit
26 display unit
261 display information storage section
263 display
28 control unit
100 power consumption system
102 electric light
104 air conditioner
106 elevator
110 non-controllable apparatus group (uncontrollable apparatus)
120 control target (controllable apparatus)
130 cloud

1. A display device, comprising:
a storage unit configured to store display information corresponding to a degree of divergence between a user's desired value and a set value; and
a display unit comprising a display configured to display the display information corresponding to the degree of divergence.

2. A display device according to claim 1, wherein the display information expresses a comfortability corresponding to the degree of divergence.

3. A display device according to claim 1, wherein the display information comprises an emoticon for expressing a comfortability.

4. A display device configured to communicate to/from a power control device that is configured to control power of a power consumption system comprising a plurality of apparatus, the display device comprising:
an input unit configured to specify a desired set value for each of the plurality of apparatus or a power consumption system comprising the plurality of apparatus; and
a display unit configured to display a display content corresponding to a degree of divergence in real time when an amount of upper limit power for the entire power consumption system comprising the plurality of apparatus is set, the degree of divergence being calculated based on a comparison between an actual set value for the plurality of apparatus having an amount of power being subjected to demand control based on an evaluation function set for the plurality of apparatus and the desired set value specified through the input unit.

5. A display device according to claim 4, further comprising a communication unit configured to communicate:
setting information on the evaluation function having a peak value correlated with the desired set value specified for each of the plurality of apparatus or the power consumption system comprising the plurality of apparatus; and
display information corresponding to the degree of divergence between the actual set value and the desired set value.

6. A display device according to claim 4, wherein the display content to be displayed on the display unit comprises a mark that allows a degree of tolerance forced on a subject person who is subject to influence of the plurality of apparatus to be visually identified.

7. A display device according to claim 4, wherein the display content to be displayed on the display unit comprises a ratio of power and a change in control for each of the plurality of apparatus.

8. A power control system, comprising:
the display device of claim 1; and
a power control device configured to control power of a power consumption system comprising a plurality of apparatus comprising a controllable apparatus and an uncontrollable apparatus, the power control device comprising:
an information acquisition unit configured to acquire an amount of power of the controllable apparatus and an amount of current power of the entire power consumption system; and
a demand control unit configured to control the amount of power of the controllable apparatus based on an evaluation function set for each of the controllable apparatus when an amount of upper limit power for the entire power consumption system is set.

9. A power control system according to claim 8, wherein the demand control unit is further configured to conduct the control so as to eliminate a difference between the amount of the upper limit power and the amount of the current power of the entire power consumption system.

10. A power control system according to claim 9, wherein the demand control unit is further configured to compare a derivative value derived from the evaluation function between the controllable apparatus, and control the derivative value derived from the evaluation function so as to become equal between the controllable apparatus.

11. A display method, comprising:
an input step of specifying a desired set value for each of a plurality of apparatus or a power consumption system comprising the plurality of apparatus; and
a display step of displaying a display content corresponding to a degree of divergence in real time when an amount of upper limit power for the entire power consumption system comprising the plurality of apparatus is set, the degree of divergence being calculated based on a comparison between an actual set value for the plurality of apparatus having an amount of power being subjected to demand control based on an evaluation function set for the plurality of apparatus and the specified desired set value.

12. A display method according to claim 11, further comprising a communication step of communicating:
setting information on the evaluation function having a peak value correlated with the desired set value specified for each of the plurality of apparatus or the power consumption system comprising the plurality of apparatus; and
display information corresponding to the degree of divergence between the actual set value and the desired set value.

13. A display method according to claim 11, wherein the display content comprises a mark that allows a degree of tolerance forced on a subject person who is subject to influence of the plurality of apparatus to be visually identified.

14. A display method according to claim 11, wherein the display content comprises a ratio of power and a change in control for each of the plurality of apparatus.

15. A power control method, comprising:
the display method of claim 11; and
a power control method for controlling power of a power consumption system comprising a plurality of apparatus comprising a controllable apparatus and an uncontrollable apparatus, the power control method comprising:
an information acquisition step of acquiring an amount of power of the controllable apparatus and an amount of current power of the entire power consumption system; and
a control step of controlling the amount of power of the controllable apparatus based on an evaluation function set for each of the controllable apparatus when an amount of upper limit power for the entire power consumption system is set.

16. A power control method according to claim 15, wherein the control step comprises conducting the control so as to eliminate a difference between the amount of the upper limit power and the amount of the current power of the entire power consumption system.

17. A power control method according to claim 16, wherein the control step comprises comparing a derivative value derived from the evaluation function between the controllable apparatus, and controlling the derivative value derived from the evaluation function so as to become equal between the controllable apparatus.

18. A non-transitory computer-readable storage medium storing a display program for causing a computer to execute:
an input procedure of specifying a desired set value for each of a plurality of apparatus or a power consumption system comprising the plurality of apparatus; and
a display procedure of displaying a display content corresponding to a degree of divergence in real time when an amount of upper limit power for the entire power consumption system comprising the plurality of apparatus is set, the degree of divergence being calculated based on a comparison between an actual set value for the plurality of apparatus having an amount of power being subjected to demand control based on an evaluation function set for the plurality of apparatus and the specified desired set value.

19. A non-transitory computer-readable storage medium storing a display program according to claim 18, further comprising a communication procedure of communicating:
setting information on the evaluation function having a peak value correlated with the desired set value specified for each of the plurality of apparatus or the power consumption system comprising the plurality of apparatus; and
display information corresponding to the degree of divergence between the actual set value and the desired set value.

20. A non-transitory computer-readable storage medium storing a display program according to claim 18, wherein the display content comprises a mark that allows a degree of tolerance forced on a subject person who is subject to influence of the plurality of apparatus to be visually identified.

21. A non-transitory computer-readable storage medium storing a display program according to claim 18, wherein the display content comprises a ratio of power and a change in control for each of the plurality of apparatus.

22. A non-transitory computer-readable storage medium storing a power control program, comprising:
the display program of claim 18; and
a power control program for controlling power of a power consumption system comprising a plurality of apparatus comprising a controllable apparatus and an uncontrollable apparatus, the power control program comprising:
an information acquisition procedure of acquiring an amount of power of the controllable apparatus and an amount of current power of the entire power consumption system; and
a control procedure of controlling the amount of power of the controllable apparatus based on an evaluation function set for each of the controllable apparatus when an amount of upper limit power for the entire power consumption system is set.

23. A non-transitory computer-readable storage medium storing a power control program according to claim 22, wherein the control procedure causes the computer to conduct the control so as to eliminate a difference between the amount of the upper limit power and the amount of the current power of the entire power consumption system.

24. A non-transitory computer-readable storage medium storing a power control program according to claim 23, wherein the control procedure causes the computer to compare a derivative value derived from the evaluation function between the controllable apparatus, and control the derivative value derived from the evaluation function so as to become equal between the controllable apparatus.
